(19) United States
(12) Patent Application Publication
(10) Pub. No.: US 2007/0182495 A1
(43) Pub. Date: Aug. 9, 2007

(54) Oscillator systems and methods

(76) Inventor: Ravindar M. Lall, Portland, OR (US)

Correspondence Address: MACPHERSON KWOK CHEN & HEID LLP, 2033 GATEWAY PLACE, SUITE 400, SAN JOSE, CA, 95110, US

(21) Appl. No.: 11/350,509

(22) Filed: Feb. 9, 2006

(51) Int. Cl. H03L 7/00

(52) U.S. Cl. 331/25

(57) ABSTRACT

Systems and methods are disclosed herein to provide improved oscillator techniques. For example, in accordance with an embodiment of the present invention, an oscillator includes at least a first current source to generate at least a first current for capacitors that provide input signals for corresponding comparators. The comparators compare the input signals to reference signals and provide the results to a latch, which provides an oscillator output signal and controls the charging and discharging of the capacitors that provide the input signals.

### TECHNICAL FIELD

The present invention relates generally to electrical circuits and, more particularly, to oscillators.

### BACKGROUND

There are a number of different circuit techniques for generating a clock signal. For example, ring oscillators, differential oscillators, and Schmitt triggers (e.g., a current over capacitance with Schmitt trigger clock signal generator) represent a few exemplary approaches for generating a clock signal.

However, the clock signal generated by these conventional approaches may vary significantly with process, voltage, and/or temperature and may require trimming on a die-by-die basis. Furthermore, these conventional approaches for oscillators typically require a divide-by-two circuit to achieve a fifty percent duty cycle with the desired clock frequency for the specific application. As a result, there is a need for improved clock generation techniques.

### SUMMARY

In accordance with one embodiment of the present invention, an oscillator includes at least a first current source adapted to generate at least a first current and a second current; at least a first and second capacitor responsive to the first and second current, respectively, to provide a corresponding first input signal and a second input signal; a first comparator adapted to receive the first input signal and compare to a first reference signal to provide a first comparator output signal; a second comparator adapted to receive the second input signal and compare to a second reference signal to provide a second comparator output signal; and a latch adapted to receive the first and second comparator output signals and provide at least one oscillator output signal, wherein the at least one oscillator output signal controls a charging and a discharging of the first and second capacitors that provide the corresponding first and second input signals.

In accordance with another embodiment of the present invention, an integrated circuit includes means responsive to a first and second current for providing a first and second input signal; means for comparing the first and second input signals to at least one reference signal to provide at least a first and second signal; and means responsive to the first and second signal for providing at least one oscillator output signal, wherein the at least one oscillator output signal controls the providing means for the first and second input signal.

In accordance with another embodiment of the present invention, a method of providing an oscillating signal includes generating a first and second signal; comparing the first and second signals to a first and second reference signal, respectively, to provide a first and second comparator signal; and providing a first and second oscillator output signal based on the first and second comparator signals, wherein the first and second oscillator output signals control the generating of the first and second signals.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 shows a circuit block diagram illustrating an oscillator in accordance with an embodiment of the present invention.

Embodiments of the present invention and their advantages are best understood by referring to the detailed description that follows. It should be appreciated that like reference numerals are used to identify like elements illustrated in one or more of the figures.

### DETAILED DESCRIPTION

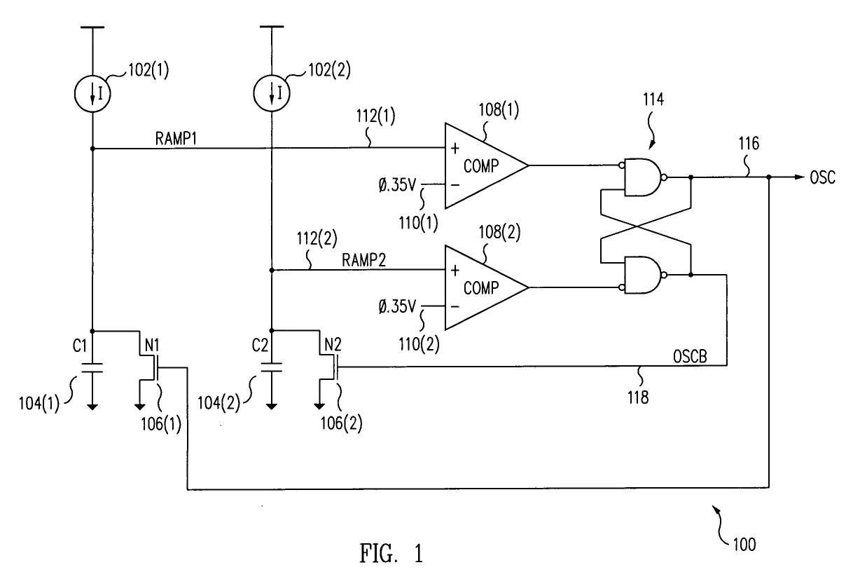

FIG. 1 shows a circuit block diagram illustrating an oscillator 100 in accordance with an embodiment of the present invention. Oscillator 100 may be implemented within a programmable logic device (PLD) (such as a field programmable gate array (FPGA) or a complex PLD (CPLD), a clock generator integrated circuit (e.g., a programmable clock generator chip), an application specific IC (ASIC), or any other type of circuit requiring an oscillator signal or other form of clock or timing signal.

Oscillator 100 includes current sources 102, capacitors 104, transistors 106, comparators 108, and a latch 114 (e.g., an SR latch). In operation, current sources 102(1) and 102(2) charge capacitors 104(1) and 104(2), respectively, to generate corresponding input signals 112(1) and 112(2) (labeled RAMPl and RAMP2 as shown), respectively. Input signal 112(1) is compared to a first reference signal 110(1) by comparator 108(1), which provides its result to latch 114. Similarly, input signal 112(2) is compared to a second reference signal 110(2) by comparator 108(2), which provides its result to latch 114.

First reference signal 110(1) and second reference signal 110(2) may both provide, for example, 0.35 volts or any other desired value, depending upon the application or requirements. Alternatively, first reference signal 110(1) and second reference signal 110(2) may each provide reference voltage levels that are different from each other, depending upon the desired application or requirements.

When input signal 112(1) exceeds the voltage level provided by first reference signal 110(1), comparator 108(1) provides a logical high signal level to latch 114, which sets latch 114. Therefore, latch 114 asserts a logical high signal level on an output signal 116 (labeled OSC), which switches on transistor 106(1) to discharge capacitor 104(1). Furthermore, latch 114 switches to remove a logical high signal level that was applied on an output signal 118 (labeled OSCB) and asserts a logical low signal level on output signal 118 to switch off transistor 106(2) and allow capacitor 104(2) to charge.

When input signal 112(2) exceeds the voltage level provided by second reference signal 110(2), comparator 108(2) provides a logical high signal level to latch 114, which resets latch 114. Consequently, transistor 106(2) is switched on by a logical high signal level on output signal 118 to discharge capacitor 104(2), and transistor 106(1) is switched off by a logical low signal level on output signal 116 to allow capacitor 104(1) to charge.

This process of charging and discharging capacitors 104(1) and 104(2) as described may be continually repeated by circuit 100 to provide an oscillator output signal (e.g., output signal 116). The oscillator output signal for this specific example provides a fifty percent duty cycle, which may provide certain advantages over some conventional techniques that require the conventional oscillator to operate at twice the frequency, with a divide-by-two circuit employed to ultimately provide the desired oscillator duty cycle of fifty percent.

Current sources 102(1) and 102(2), for example, may be generated by one or more conventional constant or fixed current source generators. For example, current sources 102 may be provided by one or more bias generators that are bandgap-based circuits and that provide trimmed current values to the desired specifications for the application. Additionally, capacitors 104, for example, may represent low voltage coefficient capacitors. Thus, the capacitance of capacitors 104 and the current provided by current sources 102 would not vary appreciably with voltage and temperature.

First reference signal 110(1) and second reference signal 110(2), for example, may be generated by one or more bandgap-type voltage reference circuits. For example, first reference signal 110(1) and second reference signal 110(2) may be provided by one or more accurate bandgap-type voltage reference generators that provide trimmed voltage values to the desired specifications for the application. Furthermore, the comparator delay associated with comparators 108 may be fairly constant and may represent only a small portion of the oscillator period for circuit 100. Consequently, circuit 100 may generate a clock signal, which is generally independent of supply voltage and temperature variations.

Systems and methods are disclosed herein to provide improved oscillator techniques. For example, in accordance with an embodiment of the present invention, an oscillator circuit is disclosed that generates an accurate clock having a frequency that may vary only slightly with voltage and temperature (e.g., plus or minus two percent), with any process dependence optionally trimmed out (e.g., in a conventional fashion). The oscillator circuit, for example, may be implemented using complementary metal oxide semiconductor (CMOS) technology (i.e., a CMOS oscillator). As a specific example, the oscillator circuit may provide a fifty percent duty cycle oscillator signal that is insensitive to power supply and temperature variations, relatively simple to construct and implement, and requires very little die area to implement.

It should also be understood that the techniques disclosed herein may be employed for an oscillator circuit that provides a duty cycle that is different than a fifty percent duty cycle. For example, the current values for current source 102(1) and/or 102(2), the capacitance values for capacitors 104(1) and/or 104(2), and/or the reference voltage levels for first reference signal 110(1) and/or second reference signal 110(2) may be adjusted or determined for a particular design, as would be understood by one skilled in the art, to vary the duty cycle for the oscillator output signal (e.g., output signal 116) to a desired duty cycle value.

Embodiments described above illustrate but do not limit the invention. It should also be understood that numerous modifications and variations are possible in accordance with the principles of the present invention. Accordingly, the scope of the invention is defined only by the following claims.

What is claimed is:

1. An oscillator comprising:
at least a first current source adapted to generate at least a first current and a second current;
at least a first and second capacitor responsive to the first and second current, respectively, to provide a corresponding first input signal and a second input signal;
a first comparator adapted to receive the first input signal and compare to a first reference signal to provide a first comparator output signal;
a second comparator adapted to receive the second input signal and compare to a second reference signal to provide a second comparator output signal; and
a latch adapted to receive the first and second comparator output signals and provide at least one oscillator output signal, wherein the at least one oscillator output signal controls a charging and a discharging of the first and second capacitors that provide the corresponding first and second input signals.

2. The oscillator of claim 1, wherein the latch comprises an SR latch.

3. The oscillator of claim 1, wherein the at least one oscillator output signal comprises at least a first oscillator output signal having a fifty percent duty cycle.

4. The oscillator of claim 1, wherein the at least first current source comprises:
a first current source adapted to provide the first current to the first capacitor, wherein the first capacitor provides the first input signal by charging based on the first current; and
a second current source adapted to provide the second current to the second capacitor, wherein the second capacitor provides the second input signal by charging based on the second current.

5. The oscillator of claim 1, wherein the first and second capacitors comprise low voltage coefficient capacitors.

6. The oscillator of claim 1, further comprising:
a first transistor coupled to the first capacitor;
a second transistor coupled to the second capacitor; and
wherein the at least one oscillator output signal comprises a first and second oscillator output signal, wherein the first transistor is adapted to receive the first oscillator output signal which controls the charging and discharging of the first capacitor via the first transistor, and the second transistor is adapted to receive the second oscillator output signal which controls the charging and discharging of the second capacitor via the second transistor.

7. The oscillator of claim 1, wherein the oscillator is implemented within a programmable logic device.

8. The oscillator of claim 1, wherein the at least first current source is generated by at least one bandgap-based circuit adapted to trim the first and second current.

9. An integrated circuit comprising:
means responsive to a first and second current for providing a first and second input signal;
means for comparing the first and second input signals to at least one reference signal to provide at least a first and second signal; and
means responsive to the first and second signal for providing at least one oscillator output signal, wherein the at least one oscillator output signal controls the providing means for the first and second input signal.

10. The integrated circuit of claim 9, further comprising means for generating the first and second current.

11. The integrated circuit of claim 9, further comprising means for generating the at least one reference signal.

12. The integrated circuit of claim 9, wherein the at least one oscillator output signal comprises at least a first oscillator output signal having a fifty percent duty cycle.

13. The integrated circuit of claim 9, wherein the integrated circuit comprises a programmable logic device.

14. A method of providing an oscillating signal, the method comprising:
generating a first and second signal;
comparing the first and second signals to a first and second reference signal, respectively, to provide a first and second comparator signal; and
providing a first and second oscillator output signal based on the first and second comparator signals, wherein the first and second oscillator output signals control the generating of the first and second signals.

15. The method of claim 14, further comprising providing a first and second current, wherein the generating of the first and second signals is based on the first and second current.

16. The method of claim 15, wherein the generating of the first and second signals comprises charging a first and second capacitor, respectively, with the corresponding first and second current.

17. The method of claim 15, wherein the generating of the first and second signals comprises charging a first and second capacitor, respectively, with the corresponding first and second current, and wherein the first and second oscillator output signals control the generating of the first and second signals by selectively controlling the discharging and charging of the first and second capacitors.

18. The method of claim 14, further comprising providing the first and second reference signals.

19. The method of claim 14, wherein the first oscillator output signal comprises a fifty percent duty cycle clock signal.

20. The method of claim 14, wherein the first and second reference signals provide approximately the same reference voltage.
